(19) United States
(12) Patent Application Publication
(10) Pub. No.: US 2025/0277872 A1
(43) Pub. Date: Sep. 4, 2025

(54) CIRCUITS AND METHODS FOR SENSING CURRENT IN RESONANT TANKS OF SWITCHING POWER SUPPLIES

(71) Applicant: Navitas Semiconductor Limited, Dublin (IE)

(72) Inventors: Xiucheng HUANG, Torrance, CA (US); Weijing DU, Torrance, CA (US); Yun ZHOU, Shenzhen (CN)

(73) Assignee: Navitas Semiconductor Limited, Dublin (IE)

(21) Appl. No.: 19/067,056

(22) Filed: Feb. 28, 2025

(30) Foreign Application Priority Data
Mar. 1, 2024 (CN) 202410238639.7

(51) Int. Cl. G01R 31/40; G01R 19/00

(52) U.S. Cl. CPC G01R 31/40; G01R 19/00

(57) ABSTRACT

A circuit is disclosed. The circuit includes a first semiconductor switch connected to a second semiconductor switch at a switch node, an input voltage coupled to the first semiconductor switch, a ground coupled to the second semiconductor switch, a resonant circuit coupled to the first and second semiconductor switches, the resonant circuit having an inductor in series with a resonant capacitor coupled to the input voltage, and a sense resistor, where a voltage across the sense resistor is proportional to a current in the resonant circuit. In one aspect, the circuit further includes a sense capacitor coupled between the resonant capacitor and the sense resistor. In another aspect, inductor is coupled in parallel with a resonant capacitor.

### CROSS REFERENCE TO RELATED APPLICATIONS

This application claims priority to Chinese provisional patent application no. 202410238639.7, for “METHOD FOR SENSING RESONANT TANK CURRENT OF SWITCHING POWER SUPPLY” filed on Mar. 1, 2024, which is hereby incorporated by reference in entirety for all purposes.

### FIELD

The described embodiments relate generally to power converters, and more particularly, the present embodiments relate to systems and methods for sensing current in resonant tanks of switching power supplies.

### BACKGROUND

With the development of power electronics, the industry has put forward higher requirements for the power density of a switching power supply. Soft switching technology can enable a power device to achieve zero-voltage switching-on (ZVS) and zero-current switching-off (ZCS), effectively reducing the switching loss of the converter. Current soft switching topologies may include a resonant tank, that is, a network composed of a resonant capacitor Cᵣ and a resonant inductor Lᵣ. Through the resonance of Cᵣ and Lᵣ, a power device can be enabled to achieve ZVS and ZCS. For soft switching topologies, accurate and efficient sensing of the resonant tank current is useful.

### SUMMARY

In some embodiments, a circuit is disclosed. The circuit includes a first semiconductor switch connected to a second semiconductor switch at a switch node; an input voltage coupled to the first semiconductor switch; a ground coupled to the second semiconductor switch; a resonant circuit coupled to the first and second semiconductor switches, the resonant circuit having an inductor in series with a resonant capacitor coupled to the input voltage; and a sense resistor, where a voltage across the sense resistor is proportional to a current in the resonant circuit.

In some embodiments, the circuit further includes a sense capacitor coupled between the resonant capacitor and the sense resistor.

In some embodiments, the resonant circuit includes a transformer having a primary side and a secondary side.

In some embodiments, the resonant capacitor is coupled to a drain terminal of the first semiconductor switch.

In some embodiments, the input voltage is coupled to the drain terminal of the first semiconductor switch.

In some embodiments, the sense resistor is coupled between the resonant capacitor and the ground.

In some embodiments, the sense capacitor is a first sense capacitor and where the circuit further includes a second sense capacitor coupled to the sense resistor.

In some embodiments, the circuit further includes a control circuit coupled to the sense resistor and arranged to sense the voltage across the resistor.

In some embodiments, a circuit is disclosed. The circuit includes a first semiconductor switch connected to a second semiconductor switch at a switch node; an input terminal coupled to the first semiconductor switch; a ground coupled to the second semiconductor switch; a resonant circuit coupled to the first and second semiconductor switches, the resonant circuit having an inductor in parallel with a resonant capacitor coupled to the input terminal; and a sense resistor coupled to the second semiconductor switch, where a voltage across the sense resistor is proportional to a current in the resonant circuit.

In some embodiments, a method of operating a circuit is disclosed. The method includes: providing a first semiconductor switch; providing a second semiconductor switch coupled to the first semiconductor switch at a switch node; providing an input terminal coupled to the first semiconductor switch; providing a ground coupled to the second semiconductor switch; providing a resonant circuit coupled to the first and second semiconductor switches, the resonant circuit having an inductor in series with a resonant capacitor coupled to the input terminal; and sensing a voltage across a sense resistor that is proportional to a current in the resonant circuit, where the sense resistor is coupled to the second semiconductor switch.

### BRIEF DESCRIPTION OF THE DRAWINGS

FIG. 1 is a schematic of a half-bridge LLC converter with components for sensing a resonant tank current according to certain aspects of the present disclosure;

FIG. 2 is a set of plots that demonstrate a resonant tank current of a half-bridge LLC converter according to certain aspects of the present disclosure;

FIG. 3 is a schematic of a half-bridge flyback converter with components for sensing a resonant tank current according to certain aspects of the present disclosure;

FIG. 4 is a set of plots that demonstrate a resonant tank current of a asymmetric half-bridge flyback converter according to certain aspects of the present disclosure;

FIG. 5 is a schematic of an active clamp flyback converter with components for sensing a resonant tank current according to certain aspects of the present disclosure;

FIG. 6A is a schematic of a system for sensing a resonant tank current according to certain aspects of the present disclosure; and

FIG. 6B is a schematic of an alternative system for sensing a resonant tank current according to certain aspects of the present disclosure.

### DETAILED DESCRIPTION

Circuits, devices and related techniques disclosed herein relate generally to power converters. More specifically, circuits, devices and related techniques disclosed herein relate to systems and methods for sensing current in resonant tanks of switching power supplies. Embodiments of the disclosure enable use of lossless resonant tank current sensing on the high side in power converter topologies such as, but not limited to, asymmetric half-bridge (AHB), inductor-inductor-capacitor (LLC) half-bridge LLC converters, and active-clamp-flyback (ACF) converters. Circuits and techniques disclosed herein can detect a resonant tank current in switching power supplies relatively accurately and with relatively high efficiently by use of a passive network that can include a sensing capacitor and a sensing resistor.

In current approaches, current sensing solutions can use a sensing resistor or a sensing capacitor. The sensing resistor method can cause ohmic losses and can reduce efficiency of the converter. The sensing capacitor method can be lossless, however it may work on the low-side only since the sensing capacitor is connected to the power ground. Thus, the capacitor sensing method can only be used in topologies with the transformer of the half-bridge converter being disposed on the low side. Embodiments of the disclosure can enable sensing of a resonant tank current on the high side as well as on the low side. In some embodiments, a controller circuit can use the sensed current for power converter loop control to provide for stable and reliable operation of the convert, and to prevent overcurrent in the power switches. Various inventive embodiments are described herein, including methods, processes, systems, devices, and the like.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

In current approaches, asymmetric half-bridge (AHB), inductor-inductor-capacitor (LLC) half-bridge LLC converters, and active-clamp-flyback (ACF) topologies may be used in power converter circuits. In current approaches, during start-up and load-shedding process of in a half-bridge LLC converter, the resonant tank current can appear to have an excessive amplitude, and the converter can have a risk of entering a capacitive region. Embodiments of the disclosure enable sensing of the resonant tank current to ensure safe and stable operation of the converter. The resonant tank can be referred to as a resonant cavity

In current approaches, current sensing solutions can be either a resistor sensing or capacitor sensing. The resistor sensing method can cause ohmic losses and can reduce efficiency of the converter. The capacitor sensing method can be a lossless current sensing method, however, can be used on the low side only since one end of the resonant capacitor Cᵣ is connected to a power ground. In current approaches, relatively complex control circuit for capacitive sensing is used in power converters, thus increasing costs. Embodiment of the disclosure enable relatively simple control scheme thereby saving costs.

In current approaches, when an output voltage of the AHB flyback converter drops, due to a mismatch between a voltage of the resonant capacitor V_{cr} and the output voltage Vₒ, a large current stress can occur in the resonant tank, which may further cause over-current damage to a synchronous control switch. Therefore, the synchronous control switch of the AHB flyback converter may require cycle-by-cycle overcurrent protection. The resonant tank of the AHB flyback converter can be disposed on the high side or the low side. In addition, the AHB flyback converter can work in a peak current control mode, using a controller circuit to sense a peak current of a main control switch. Embodiments of the disclosure enable use of switching devices with a lossless current sensing function, such as Navitas' GaNsense™ technology, that are disposed on the low side or on the high side.

In current approaches, during dynamic testing of a ACF power converter, the resonant tank of the ACF converter may experience a large current stress. Embodiments of the disclosure can enable safe and reliable test and operation of ACF converters.

In some embodiments, the resonant capacitor Cᵣ and the resonant inductor Lᵣ can form a resonant tank of a switching power supply. The resonant inductor may be an independent inductor or a leakage inductance of a transformer. In the half-bridge LLC converter, the resonant inductor Lᵣ can generally be an independent inductor. In the AHB flyback converter and the ACF converter, the resonant inductor can generally be a leakage inductance of a transformer. In various embodiments, one end of the resonant capacitor Cᵣ can be directly connected to the input voltage, and the other end thereof can be connected to the sensing capacitor.

In some embodiments, the sensing capacitor and the sensing resistor can be connected in series to form a passive RC network. By sensing a difference between input voltage and voltage of a resonant capacitor, a current value of the resonant tank can be accurately obtained. Embodiment of the disclosure enable use of a voltage of the sensing resistor to represent current information of a resonant tank, and a calculation formula is as follows:

$${V}_{sense} = {C}_{sense} \frac{d ( {V}_{in} \pm {V}_{cr} )}{dt} {R}_{sense} \qquad ( 1 )$$

where Cₛₑₙₛₑ is a capacitance of the sensing capacitor, Rₛₑₙₛₑ is the resistance of the sensing resistor, Vₛₑₙₛₑ is the voltage of the sensing resistor, Vᵢₙ is the input voltage, and V_{cr} is the voltage of the resonant capacitor. In formula (1), the half-bridge LLC converter and the asymmetric half-bridge flyback converter are marked with a ‘-’ sign. Formula (1) can be rewritten as formula (2):

$${V}_{sense} = {C}_{sense} \frac{d ( {V}_{in} - {V}_{cr} )}{dt} {R}_{sense} \qquad ( 2 )$$

In formula (1), the active clamp flyback converter is marked with a ‘+’ sign. Formula (1) can be rewritten as formula (3):

$${V}_{sense} = {C}_{sense} \frac{d ( {V}_{in} + {V}_{cr} )}{dt} {R}_{sense} \qquad ( 3 )$$

In the present disclosure, the sensing resistor Rₛₑₙₛₑ can be connected in parallel with a capacitor or diode to further regulate amplitude and phase of the voltage Vₛₑₙₛₑ of the sensing resistor.

In order to make the technical advantages of the present disclosure clear, circuits and methods for sensing a resonant tank current of switching power supplies are described in detail below with reference to the accompanying drawings. In particular, the embodiments described herein are merely used to explain the present disclosure and are not intended to limit the present disclosure.

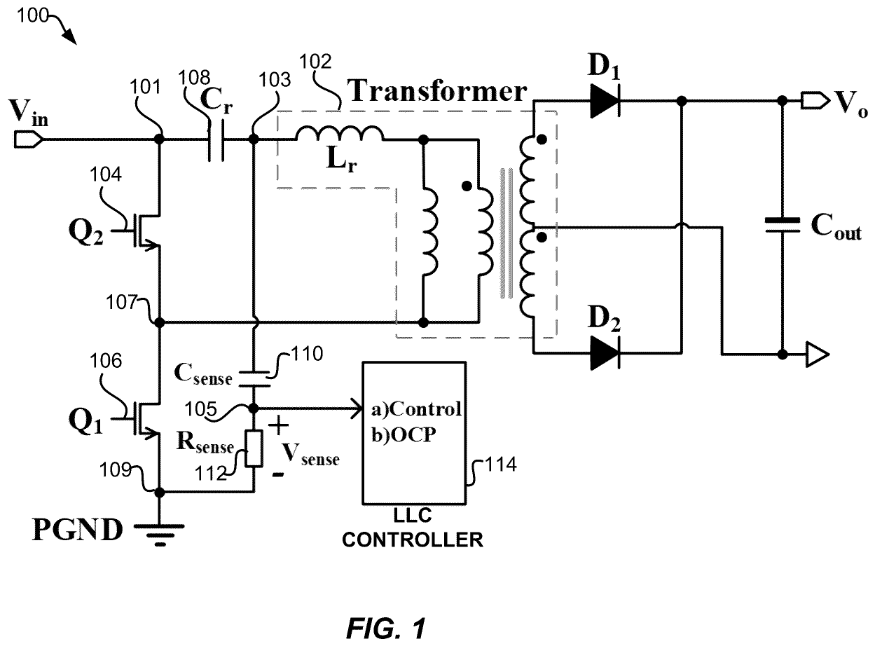

FIG. 1 is a schematic of a half-bridge LLC converter 100 with components for sensing a resonant tank current, according to certain aspects of the present disclosure. The half-bridge LLC converter 100 can include a transformer 102, a first switch 106 (labeled Q₁ in FIG. 1), a second switch 104 (labeled Q₂ in FIG. 1), a resonant capacitor 108 (labeled Cᵣ in FIG. 1), a sense capacitor 110 (labeled Cₛₑₙₛₑ in FIG. 1), a sense resistor 112 (labeled Rₛₑₙₛₑ in FIG. 1), and an LLC controller 114. The half-bridge LLC converter 100 can also include a number of nodes, such as node 101, node 103, node 105, node 107, and node 109. Additionally, the LLC converter 100 can include a voltage input Vᵢₙ and a ground location PGND. Since the second switch 104 is closer to the voltage input Vᵢₙ than the first switch 106, the second switch 104 can be referred to as a high side switch and the first switch 106 can be referred to as a low side switch. In the half-bridge LLC converter 100, the first switch 106 can act as a main switch and the second switch 104 can act as a synchronous switch. In some examples, the first switch 106 can operate without a bootstrap power supply.

The transformer 102 can include a primary side and a secondary side. The primary side of the transformer 102 can include a resonant inductor (labeled Lᵣ in FIG. 1). The primary side of the transformer 102 and the resonant capacitor 108 can form the resonant tank. The resonant tank can be referred to as a resonant cavity. Current that flows through the resonant tank can be referred to as a tank current. The resonant tank can be connected to leads (e.g., lead 101 and lead 107) adjacent to the second switch 104 or high side switch. Thus, the half-bridge LLC converter 100 can have an arrangement with a high side resonant tank.

One end of the resonant capacitor 108 can be connected to node 103. Another end of the resonant capacitor 108 can be connected to the voltage input Vᵢₙ via the lead 101. The connection to voltage input Vᵢₙ can act as a ‘static point’ for the resonant capacitor 108. The tank current can be sensed easier when the resonant capacitor 108 has the “static point”. A first end of the sense capacitor 110 can be connected to node 103 and a second end of the sense capacitor 110 can be connected to node 105. A first end of the sense resistor 112 can be connected to node 105 and second end of the sense resistor 112 can be connected to node 109. A voltage across the sense resistor 112 can be called a sense voltage (labeled Vₛₑₙₛₑ in FIG. 1). The LLC controller 114 can be connected to node 105.

The sense capacitor 110 and the sense resistor 112 can be connected in series to form a passive RC network. By sensing a difference between the input voltage Vᵢₙ and voltage of the resonant capacitor 108, a value for the tank current of the resonant tank can be accurately obtained. The voltage Vₛₑₙₛₑ across the sense resistor 112 can represent tank current information of the resonant tank, and a calculation formula for Vₛₑₙₛₑ is as follows:

$${V}_{sense} = {C}_{sense} \frac{d ( {V}_{in} - {V}_{cr} )}{dt} {R}_{sense} \qquad ( 4 )$$

where Cₛₑₙₛₑ is a capacitance of the sense capacitor 110, Rₛₑₙₛₑ is the resistance of the sense resistor 112, Vₛₑₙₛₑ is the voltage of the sense resistor 112, Vᵢₙ is the input voltage, and V_{cr} is the voltage of the resonant capacitor 108.

In LLC converter 100, a resonant tank is disposed on a high side of the half-bridge LLC converter, Q₁ can act as a main control switch, and Q₂ can act as a synchronous control switch. Embodiment of the disclosure enable direct connection of one end of a resonant capacitor Cᵣ to an input voltage Vᵢₙ, and another end thereof to a sensing capacitor 110 labeled Cₛₑₙₛₑ. Through differential sampling of the sensing capacitor and a sensing resistor, embodiments of the disclosure can detect current of the resonant tank with relative accuracy and efficiency.

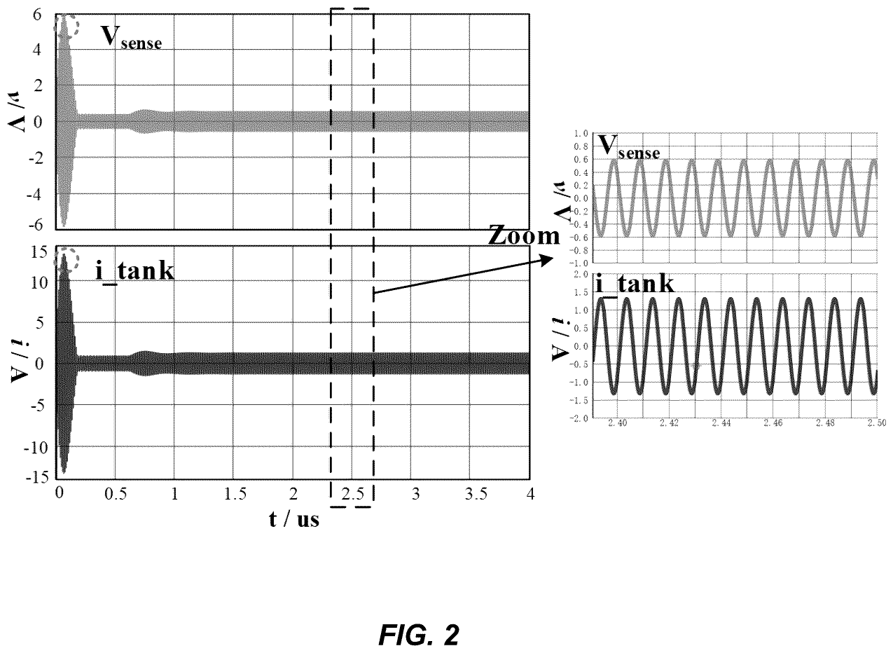

FIG. 2 shows graphs of sensed current in the tank of the half-bridge LLC converter 100, according to some embodiments. For FIG. 2, the sensing capacitor 110 Cₛₑₙₛₑ has a value of, for example, 1 nF, and sensing resistor 112 Rₛₑₙₛₑ has a value of, for example, 15Ω. It can be seen from FIG. 2 that the circuits and methods disclosed herein can accurately sense the current of the resonant tank and convert the resonant tank current into a voltage Vₛₑₙₛₑ of the sensing resistor. During a startup process of the half-bridge LLC converter, a peak current value of the resonant tank can be very large. At this time, a large voltage Vₛₑₙₛₑ can also appear across the sensing resistor. After a control circuit detects the resonant tank current by sensing the voltage Vₛₑₙₛₑ, the controller can respond relatively quickly to turn off the main switch, thereby improving the reliability of the half-bridge LLC converter. Embodiments of the disclosure can enable sensing of the resonant tank current cycle by cycle, thereby allowing the sensed current to be used as an input parameter of a control loop of the half-bridge LLC converter.

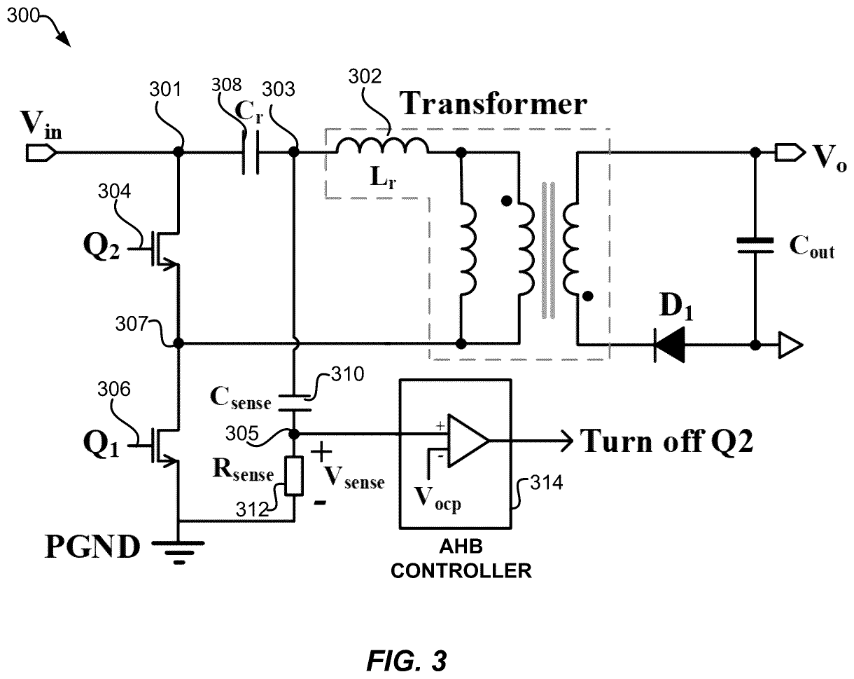

FIG. 3 is a schematic of an AHB flyback converter 300 with components for sensing a resonant tank current according to certain aspects of the present disclosure. The AHB flyback converter 300 can include a transformer 302, a first switch 306 (labeled Q₁ in FIG. 3), a second switch 304 (labeled Q₂ in FIG. 3), a resonant capacitor 308 (labeled Cᵣ in FIG. 3), a sense capacitor 310 (labeled Cₛₑₙₛₑ in FIG. 3), a sense resistor 312 (labeled Rₛₑₙₛₑ in FIG. 3), and an AHB controller 314. The AHB flyback converter 300 can also include a number of nodes, such as node 301, node 303, node 305, and node 307. Additionally, the AHB flyback converter 300 can include a voltage input Vᵢₙ and a ground location PGND. Since the second switch 304 is closer to the voltage input Vᵢₙ than the first switch 306, the second switch 304 can be referred to as a high side switch and the first switch 306 can be referred to as a low side switch. In the AHB flyback converter 300, the first switch 306 can act as a main switch and the second switch 304 can act as a synchronous switch. In some examples, the first switch 306 can operate without a bootstrap power supply.

The transformer 302 can include a primary side and a secondary side. The primary side of the transformer 302 can include a resonant inductor (labeled L in FIG. 3). The primary side of the transformer 302 and the resonant capacitor 308 can form the resonant tank. Current that flows through the resonant tank can be referred to as a tank current. The resonant tank can be connected to leads (e.g., lead 301 and lead 307) adjacent to the second switch 304 or high side switch. Thus, the AHB flyback converter 300 can have an arrangement with a high side resonant tank.

One end of the resonant capacitor 308 can be connected to node 303. Another end of the resonant capacitor 308 can be connected to the voltage input Vᵢₙ via the lead 301. The connection to voltage input Vᵢₙ can act as a ‘static point’ for the resonant capacitor 308. The tank current can be sensed easier when the resonant capacitor 308 has the “static point”. A first end of the sense capacitor 310 can be connected to node 303 and a second end of the sense capacitor 310 can be connected to node 305. A first end of the sense resistor 312 can be connected to node 305 and a second end of the sense resistor 312 can be connected to ground. A voltage across the sense resistor 312 can be called a sense voltage (labeled Vₛₑₙₛₑ in FIG. 3). The AHB controller 314 can be connected to node 305.

The sense capacitor 310 and the sense resistor 312 can be connected in series to form a passive RC network. By sensing a difference between the input voltage Vᵢₙ and voltage of the resonant capacitor 308, a value for the tank current of the resonant tank can be accurately obtained. The voltage Vₛₑₙₛₑ across the sense resistor 312 can represent tank current information of the resonant tank, and a calculation formula for Vₛₑₙₛₑ is as follows:

$${V}_{sense} = {C}_{sense} \frac{d ( {V}_{in} - {V}_{cr} )}{dt} {R}_{sense} \qquad ( 5 )$$

where Cₛₑₙₛₑ is a capacitance of the sense capacitor 310, Rₛₑₙₛₑ is the resistance of the sense resistor 312, Vₛₑₙₛₑ is the voltage of the sense resistor 312, Vᵢₙ is the input voltage, and V_{cr} is the voltage of the resonant capacitor 308. The AHB controller 314 can continuously monitor the tank current. In some examples, the AHB controller 314 can compare the monitored value of the tank current to a threshold value and can automatically turn off a switch, such as the second switch 304, if the monitored value exceeds the threshold value. The AHB controller 314 can protect switches from overload currents.

In some embodiments, the asymmetric half-bridge flyback converter 300 can operate in a peak current control mode, that uses sensing of the current in the main control switch. When the first switch acts as the main control switch, lossless current sensing of the power device can be used to improve efficiency of the converter. Embodiments of the disclosure enable connection of one end of a resonant capacitor Cᵣ to an input voltage Vᵢₙ and enable detecting current information of the resonant tank accurately and efficiently through a sensing capacitor and a sensing resistor.

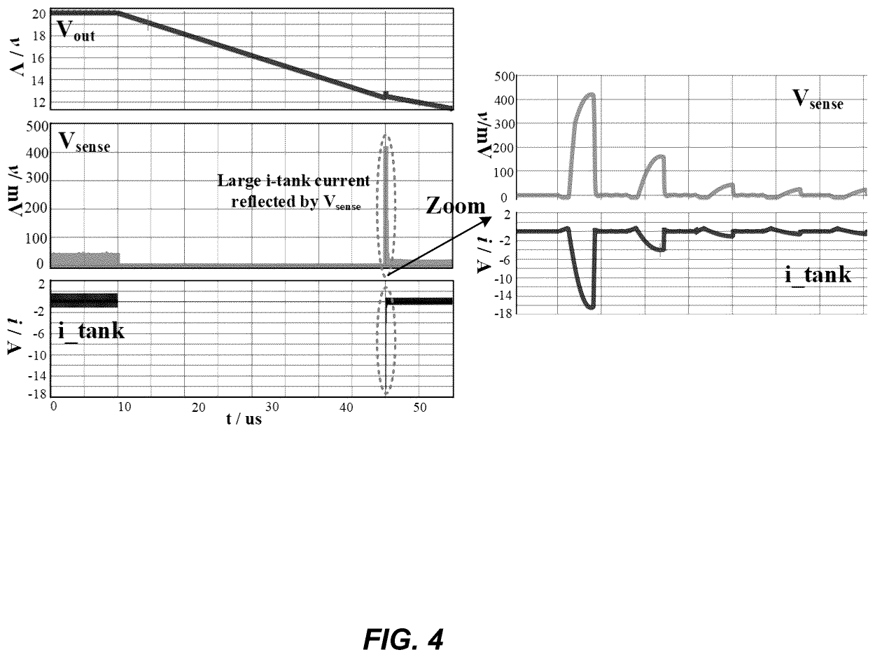

FIG. 4 shows graphs of sensed current in the tank of the asymmetric half-bridge flyback converter 300, according to some embodiments. For FIG. 4, the sensing capacitor 310 Cₛₑₙₛₑ has a value of, for example, 20 pF, and sensing resistor 312 Rₛₑₙₛₑ has a value of, for example, 2 KΩ. It can be seen from FIG. 4 that the circuits and methods disclosed herein can accurately sense the current of the resonant tank. When an output voltage of the asymmetric half-bridge flyback converter drops, a pulse current exceeding 16 A may appear in the resonant tank, which may cause damage to the second switch. By using the sensing method disclosed herein, after detecting the current information of the resonant tank, a controller circuit can compare the voltage Vₛₑₙₛₑ with an overcurrent protection setting V_{ocp}. When the controller circuit finds that Vₛₑₙₛₑ>V_{ocp}, the controller circuit can switch off the second switch relatively rapidly to prevent damage to the power switch.

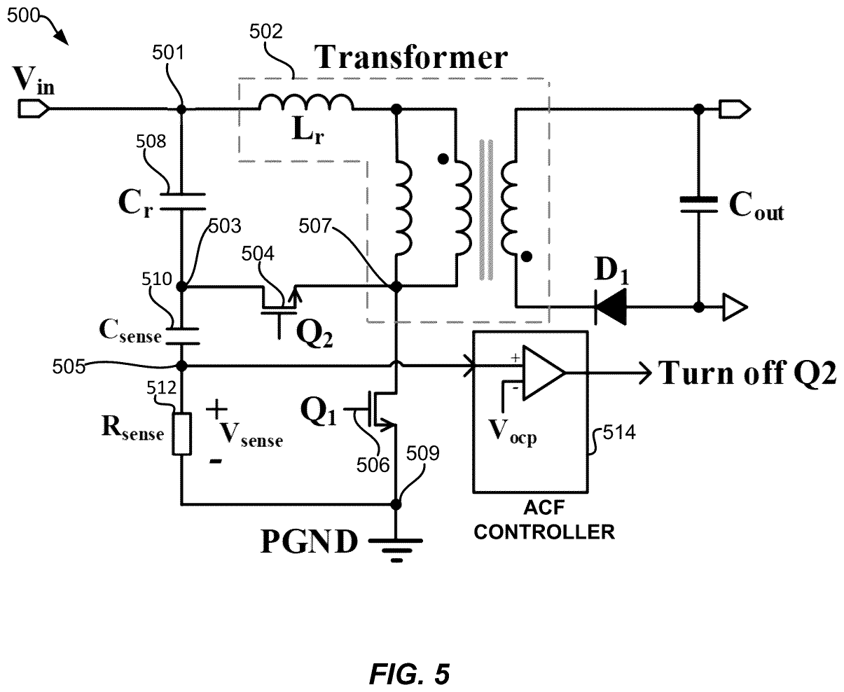

FIG. 5 is a schematic of an ACF converter 500 with components for sensing a resonant tank current according to certain aspects of the present disclosure. The ACF converter 500 can include a transformer 502, a first switch 506 (labeled Q₁ in FIG. 5), a second switch 504 (labeled Q₂ in FIG. 5), a resonant capacitor 508 (labeled Cᵣ in FIG. 5), a sense capacitor 510 (labeled Cₛₑₙₛₑ in FIG. 5), a sense resistor 512 (labeled Rₛₑₙₛₑ in FIG. 5), and an ACF controller 514. The ACF flyback converter 500 can also include a number of nodes, such as node 501, node 503, node 505, node 507, and node 509. Additionally, the ACF converter 500 can include a voltage input Vᵢₙ and a ground location PGND. Since the second switch 504 is closer to the voltage input Vᵢₙ than the first switch 506, the second switch 504 can be referred to as a high side switch and the first switch 506 can be referred to as a low side switch. In the ACF converter 500, the first switch 506 can act as a main switch and the second switch 504 can act as a synchronous switch. In some examples, the first switch 506 can operate without a bootstrap power supply.

The transformer 502 can include a primary side and a secondary side. The primary side of the transformer 502 can include a resonant inductor (labeled Lᵣ in FIG. 5). The primary side of the transformer 502 and the resonant capacitor 508 can form the resonant tank. The resonant tank can be referred to as a resonant cavity. Current that flows through the resonant tank can be referred to as a tank current. The resonant tank can be connected to leads (e.g., lead 503 and lead 507) adjacent to the second switch 504 or high side switch. Thus, the ACF converter 500 can have an arrangement with a high side resonant tank.

One end of the resonant capacitor 508 can be connected to node 503. Another end of the resonant capacitor 508 can be connected to the voltage input Vᵢₙ via the lead 501. The connection to voltage input Vᵢₙ can act as a ‘static point’ for the resonant capacitor 508. The tank current can be sensed easier when the resonant capacitor 508 has the “static point”. A first end of the sense capacitor 510 can be connected to node 503 and a second end of the sense capacitor 510 can be connected to node 505. A first end of the sense resistor 512 can be connected to node 505 and a second end of the sense resistor 512 can be connected to node 509. A voltage across the sense resistor 512 can be called a sense voltage (labeled Vₛₑₙₛₑ in FIG. 5). The ACF controller 514 can be connected to node 505.

The sense capacitor 510 and the sense resistor 512 can be connected in series to form a passive RC network. By sensing a sum of the input voltage Vᵢₙ and voltage of the resonant capacitor 508, a value for the tank current of the resonant tank can be accurately obtained. The voltage Vₛₑₙₛₑ across the sense resistor 512 can represent tank current information of the resonant tank, and a calculation formula for Vₛₑₙₛₑ is as follows:

$${V}_{sense} = {C}_{sense} \frac{d ( {V}_{in} + {V}_{cr} )}{dt} {R}_{sense} \qquad ( 6 )$$

where Cₛₑₙₛₑ is a capacitance of the sense capacitor 510, Rₛₑₙₛₑ is the resistance of the sense resistor 512, Vₛₑₙₛₑ is the voltage of the sense resistor 512, Vᵢₙ is the input voltage, and V_{cr} is the voltage of the resonant capacitor 508. The ACF controller 514 can continuously monitor the tank current. In some examples, the ACF controller 514 can compare the monitored value of the tank current to a threshold value and can automatically turn off a switch, such as the second switch 504, if the monitored value exceeds the threshold value. The ACF controller 514 can protect switches from overload currents. Embodiments of the disclosure enable connection of one end of a resonant capacitor 508 Cᵣ to the input voltage Vᵢₙ, and can enable detecting current of the resonant tank accurately and efficiently through a sensing capacitor 510 and a sensing resistor 512.

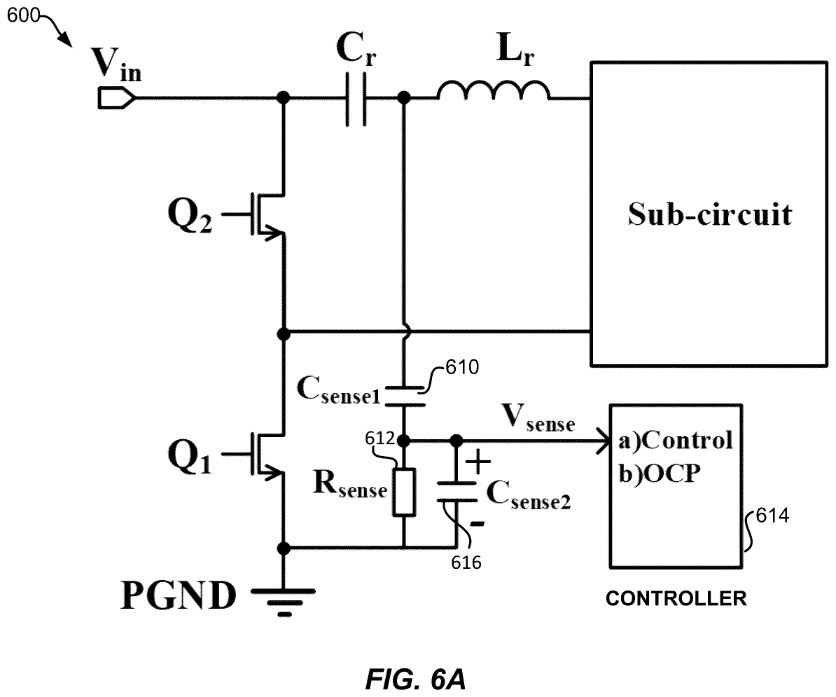

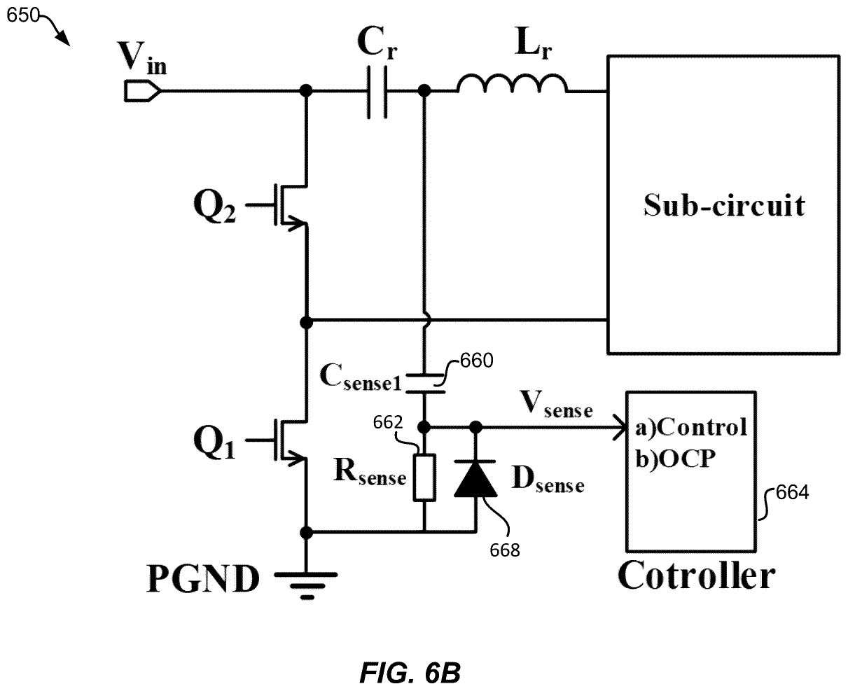

FIG. 6A is a schematic of a system 600 for sensing a resonant tank current according to certain aspects of the present disclosure. The system 600 can be similar to LLC converter 100 from FIG. 1, AHB flyback converter 300 from FIG. 3, or ACF converter 500 from FIG. 5. The system 600 can have an arrangement that includes a high side resonant tank. Additionally, the system 600 can include sensing components that can measure a tank current (e.g. resonant tank current). The sensing components can include a first sense capacitor 610 (labeled Cₛₑₙₛₑ₁ in FIG. 6A), a sense resistor 612 (labeled Rₛₑₙₛₑ in FIG. 6A), a second sense capacitor 616 (labeled Cₛₑₙₛₑ₂ in FIG. 6A), and a controller 614. The controller 614 can be LLC controller 114, AHB controller 314, or ACF controller 514. The sensing components can be similar to the passive RC networks shown in FIGS. 1, 3 and 5, but the sensing components can include the additional second sense capacitor 616. The second sense capacitor 616 can be connected in parallel with the sense resistor 612.

The sensing components can allow the controller 614 to measure (using e.g., equations (4), (5), or (6) as described above) and monitor the resonant tank current via a sensed voltage across the sense resistor 612. In some examples, the controller 614 can used the measured resonant tank current to protect components, such as a high side switch, by comparing the measured current to a threshold current value. The controller 614 can switch components off if the measured resonant tank current exceeds the threshold current value. The second sense capacitor 616 can enable an amplitude or phase adjustment of the sense voltage. The amplitude or phase adjustment can cause the sense voltage to more closely align with the resonant tank current, simplifying and improving a capability of the controller 614 to control the system 600.

FIG. 6B is a schematic of an alternative system 650 for sensing a resonant tank current according to certain aspects of the present disclosure. The system 650 can be similar to LLC converter 100 from FIG. 1, AHB flyback converter 300 from FIG. 3, or ACF converter 500 from FIG. 5. The system 650 can have an arrangement that includes a high side resonant tank. Additionally, the system 650 can include sensing components that can measure a tank current (e.g. resonant tank current). The sensing components can include a sense capacitor 660 (labeled Cₛₑₙₛₑ₁ in FIG. 6B), a sense resistor 662 (labeled Rₛₑₙₛₑ in FIG. 6B), a diode 668 (labeled Dₛₑₙₛₑ in FIG. 6B), and a controller 664. The controller 664 can be LLC controller 114, AHB controller 314, or ACF controller 514. The sensing components can be similar to passive RC networks shown in FIGS. 1, 3 and 5, but the sensing components can include the diode 668. The diode 668 can be connected in parallel with the sense resistor 662.

The sensing components can allow the controller 664 to measure (using e.g., equation (4), (5), or (6) as described above) and monitor the resonant tank current via a sensed voltage across the sense resistor 662. In some examples, the controller 664 can used the measured resonant tank current to protect components, such as a high side switch, by comparing the measured current to a threshold current value. The controller 664 can switch components off if the measured resonant tank current exceeds the threshold current value. The diode 668 can enable an amplitude or phase adjustment of the sense voltage. The amplitude or phase adjustment can cause the sense voltage to more closely align with the resonant tank current, simplifying and improving a capability of the controller 664 to control the system 650. In some examples, the adjustment can eliminate negative values of the sense voltage and protect components of the controller 664 that may be damaged by negative voltages.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the switch in use and/or operation in addition to the orientation depicted in the figures. For example, if the switch in the figures is turned over, elements described as a “bottom” surface can then be oriented “above” other elements or features. The switch can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A circuit comprising:
a first semiconductor switch connected to a second semiconductor switch at a switch node;
an input voltage coupled to the first semiconductor switch;
a ground coupled to the second semiconductor switch;
a resonant circuit coupled to the first and second semiconductor switches, the resonant circuit comprising an inductor in series with a resonant capacitor coupled to the input voltage; and
a sense resistor, wherein a voltage across the sense resistor is proportional to a current in the resonant circuit.

2. The circuit of claim 1, further comprising a sense capacitor coupled between the resonant capacitor and the sense resistor.

3. The circuit of claim 1, wherein the resonant circuit comprises a transformer having a primary side and a secondary side.

4. The circuit of claim 1, wherein the resonant capacitor is coupled to a drain terminal of the first semiconductor switch.

5. The circuit of claim 4, wherein the input voltage is coupled to the drain terminal of the first semiconductor switch.

6. The circuit of claim 1, wherein the sense resistor is coupled between the resonant capacitor and the ground.

7. The circuit of claim 2, wherein the sense capacitor is a first sense capacitor and wherein the circuit further comprises a second sense capacitor coupled to the sense resistor.

8. The circuit of claim 1, further comprising a control circuit coupled to the sense resistor and arranged to sense the voltage across the resistor.

9. A circuit comprising:
a first semiconductor switch connected to a second semiconductor switch at a switch node;
an input terminal coupled to the first semiconductor switch;
a ground coupled to the second semiconductor switch;
a resonant circuit coupled to the first and second semiconductor switches, the resonant circuit comprising an inductor in parallel with a resonant capacitor coupled to the input terminal; and
a sense resistor coupled to the second semiconductor switch, wherein a voltage across the sense resistor is proportional to a current in the resonant circuit.

10. The circuit of claim 9, further comprising a sense capacitor coupled between the resonant capacitor and the sense resistor.

11. The circuit of claim 9, wherein the resonant circuit comprises a transformer having a primary side and a secondary side.

12. The circuit of claim 9, wherein the resonant capacitor is coupled to a drain terminal of the first semiconductor switch.

13. The circuit of claim 12, wherein the input terminal is coupled to the drain terminal of the first semiconductor switch.

14. The circuit of claim 9, wherein the sense resistor is coupled between the resonant capacitor and the ground.

15. The circuit of claim 10, wherein the sense capacitor is a first sense capacitor and wherein the circuit further comprises a second sense capacitor coupled to the sense resistor.

16. A method of operating a circuit, the method comprising:
providing a first semiconductor switch;
providing a second semiconductor switch coupled to the first semiconductor switch at a switch node;
providing an input terminal coupled to the first semiconductor switch;
providing a ground coupled to the second semiconductor switch;
providing a resonant circuit coupled to the first and second semiconductor switches, the resonant circuit comprising an inductor in series with a resonant capacitor coupled to the input terminal; and
sensing a voltage across a sense resistor that is proportional to a current in the resonant circuit, wherein the sense resistor is coupled to the second semiconductor switch.

17. The method of claim 16, further comprising providing a sense capacitor that is coupled between the resonant capacitor and the sense resistor.

18. The method of claim 16, wherein the resonant circuit comprises a transformer having a primary side and a secondary side.

19. The method of claim 16, wherein the resonant capacitor is coupled to a drain terminal of the first semiconductor switch.

20. The method of claim 19, wherein the input terminal is coupled to the drain terminal of the first semiconductor switch.
